(19) United States
(12) Patent Application Publication
(10) Pub. No.: US 2008/0073713 A1
(43) Pub. Date: Mar. 27, 2008

(54) Method of fabricating semiconductor device having stress enhanced MOS transistor and semiconductor device fabricated thereby

(75) Inventors: Ki-Chul Kim, Suwon-si (KR); Dong-Suk Shin, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/785,994

(22) Filed: Apr. 23, 2007

(30) Foreign Application Priority Data
Sep. 25, 2006 (KR) 10-2006-0092855

(51) Int. Cl. H01L 27/092; H01L 21/8238

(52) U.S. Cl. 257/336; 438/217; 257/E21.633; 257/E21.634; 257/E21.64; 257/E27.062

(57) ABSTRACT

A method of fabricating a semiconductor device having a stress enhanced MOS transistor is provided. A MOS transistor may be formed in a desired, or alternatively, a predetermined region of a semiconductor substrate. A first sacrificial pattern, formed over the source and drain regions of a MOS transistor, may expose sidewall spacers and cover the upper region of the gate pattern. Thinner spacers may be formed by etching the exposed sidewall spacers using the first sacrificial pattern as an etch mask. A stress liner may be formed over the MOS transistor having the thinner spacers.

### PRIORITY STATEMENT

This application claims priority under 35 USC § 119 to Korean Patent Application No. 2006-0092855, filed on Sep. 25, 2006, in the Korean Intellectual Property Office (KIPO), the entire contents of which are herein incorporated by reference.

### BACKGROUND

1. Field

Example embodiments relate to a method of fabricating a semiconductor device having a stress enhanced MOS transistor and the semiconductor device fabricated thereby.

2. Description of the Related Art

There has been much research aimed at increasing the operating speed and enhancing the integrity of semiconductor devices. Semiconductor devices may include discrete devices, for example, MOS transistors. The smaller the gate of a MOS transistor, the more narrow the channel region under the gate. The mobility of the carrier in the channel region may have an influence on drain current. Accordingly, research of various methods for improving the mobility of the carrier by applying physical stress to the channel region has increased.

A method of forming a stress liner for applying physical stress to the channel region of a MOS transistor has been developed. The stress liner may be formed to cover the source and drain regions and the gate pattern of the MOS transistor. When the channel region under the gate pattern includes p-type impurity ions, the stress liner may be formed of a material layer which may apply tensile stress to the channel region. When the channel region under the gate pattern includes n-type impurity ions, the stress liner may be formed of a material layer which may apply compressive stress to the channel region.

A salicide technique may be used for improving the performance of a MOS transistor. According to the salicide technique, a metal silicide layer may be formed on the gate electrode and the source and drain regions of the MOS transistor, thereby reducing the electrical resistance of the gate electrode and the source and drain regions.

After a metal silicide layer is formed on the gate electrode and source and drain regions, a spacer covering sidewalls of the gate electrode may be removed, and a compressively or tensilely stressed film may be formed thereon.

However, the metal silicide layer may be damaged when the spacer is removed.

FIG. 1 is a cross-sectional view illustrating a method of forming a stress liner in a conventional MOS transistor having a metal silicide layer.

Referring to FIG. 1, an isolation layer 13 may be formed to define an active region 12 in a desired, or alternatively, a predetermined region of a semiconductor substrate 11. A gate dielectric layer 15 may be formed on the active region 12. A gate electrode 16 may be formed on the gate dielectric layer 15. The gate electrode 16 may be a polysilicon layer.

Lightly doped drains (LDDs) 23 may be formed in the active region 12 on both sides of the gate electrode 16. Spacers 20 may be formed on both sidewalls of the gate electrode 16. The spacer 20 may include an inner spacer 21 contacting the sidewall of the gate electrode 16 and an outer spacer 22 covering an outer surface of the inner spacer 21. High-concentration impurity regions 24 may be formed in the active region 12 using the spacers 20 and the gate electrode 16 as ion injection masks. As a result, the LDDs 23 may remain under the spacers 20.

A gate metal silicide layer 17 and drain metal silicide layers 25 may be formed on the gate electrode 16 and the high-concentration impurity regions 24, respectively. The gate electrode 16 and the gate metal silicide layer 17 may constitute the gate pattern 19. The LDDs 23, the high-concentration impurity regions 24, and the drain metal silicide layers 25 may constitute source and drain regions. A channel region CH is disposed in the active region 12 under the gate electrode 16. The source and drain regions, the channel region CH, the gate dielectric layer 15, the gate pattern 19, and the spacers 20 constitute a MOS transistor.

A stress liner may be formed on the MOS transistor, and thus, physical stress may be applied to the channel region CH. However, the spacers 20 may weaken the physical stress applied to the channel region CH by the stress liner. As such, it may be necessary that the spacers 20 are formed thinner to effectively apply the physical stress to the channel region CH using the stress liner.

Before forming the stress liner, the spacers 20 may be thinned by removing the outer spacer 22. A silicon nitride layer may be used as the outer spacer 22. However, an etching gas or a solution for removing the outer spacer 22 may cause damage to the metal silicide layers 17 and 25, which may cause an undesirable increase in the resistance of the gate pattern 19 and the source and drain regions.

### SUMMARY

Example embodiments provide a method of fabricating a semiconductor device in which reducing or preventing etching damage to a metal silicide layer and forming a thinner spacer may be obtained. Example embodiments also provide a semiconductor device having a stress enhanced MOS transistor.

According to example embodiments, the method may include forming a MOS transistor in a desired, or alternatively, a predetermined region of a semiconductor substrate. The MOS transistor may include source and drain regions spaced apart from one another in the semiconductor substrate, a gate pattern formed over a channel region between the source and drain regions, and sidewall spacers covering sidewalls of the gate pattern. A first sacrificial pattern covering the source and drain regions, exposing the sidewall spacers, and covering the upper region of the gate pattern may be formed. Thinner spacers may be formed by etching the exposed sidewall spacers using the first sacrificial pattern as an etch mask. A stress liner may be formed to cover the MOS transistor having the thinner spacer.

A first sacrificial layer covering the MOS transistor may be formed. A second sacrificial layer may be formed on the first sacrificial layer. The second sacrificial layer may be formed on the outer surface of the sidewall spacers to be thinner than that formed over the gate pattern and the source and drain regions. A second sacrificial pattern may be exposed by etching the second sacrificial layer until the first sacrificial layer formed on the outer surface of the sidewall spacers is exposed. The first sacrificial pattern may be formed by etching the exposed first sacrificial layer until the sidewall spacers are exposed. The second sacrificial layer may be a high-density plasma (HDP) nitride layer. Also, the second sacrificial pattern may be removed when the exposed sidewall spacers are etched. The first sacrificial pattern may be removed after the thinner spacers have been formed.

The gate pattern may include a gate metal silicide layer. The source and drain regions may include a pair of high-concentration impurity regions, a pair of lightly doped drains (LDDs), and a drain metal silicide layer on each high-concentration impurity region. Each LDD may be formed between one of the high-concentration impurity regions and the channel region.

The sidewall spacers may include an inner spacer contacting the sidewall of the gate pattern and an outer spacer covering an outer surface of the inner spacer. The inner spacer may be formed of a thermal oxide layer. The outer spacer may be formed of a silicon nitride layer. The formation of the thinner spacers may include isotropically etching the outer spacer and exposing the inner spacer. The first sacrificial pattern may be formed of a material layer having an etch selectivity according to the inner and outer spacers. The first sacrificial pattern may be formed of a titanium nitride (TiN) layer, a low temperature oxide (LTO) layer, or a combination thereof.

The channel region may include n-type or p-type impurity ions. When n-type impurity ions are injected into the channel region, the stress liner may be formed of an insulating layer having compressive stress. The insulating layer having compressive stress may be a compressive nitride layer. When p-type impurity ions are injected into the channel region, the stress liner may be formed of an insulating layer having tensile stress. The insulating layer having tensile stress may be a tensile nitride layer.

According to example embodiments, a method of fabricating a semiconductor device having a stress enhanced MOS transistor may include forming a NMOS transistor and a PMOS transistor that are spaced apart from one another in a desired, or alternatively, a predetermined region of a semiconductor substrate.

The NMOS transistor may include source and drain regions spaced apart from one another in the semiconductor substrate, a gate pattern formed over the p-channel region between the source and drain regions, and sidewall spacers covering sidewalls of the gate pattern.

The PMOS transistor may include source and drain regions spaced apart from one another in the semiconductor substrate, a gate pattern formed over the n-channel between the source and drain regions, and sidewall spacers covering sidewalls of the gate pattern.

A first sacrificial pattern covering the source and drain regions, exposing the sidewall spacers, and covering the upper regions of the gate patterns may be formed. The exposed sidewall spacers may be etched using the first sacrificial pattern as an etch mask to form thinner spacers. A tensile liner covering the NMOS transistor having the thinner spacers and a compressive liner covering the PMOS transistor having the thinner spacers may be formed.

According to example embodiments, a semiconductor device having a stress enhanced MOS transistor may include a channel region in a desired, or alternatively, a predetermined region of a semiconductor substrate. Source and drain regions may be on both sides of the channel region. The source and drain regions may include a pair of high-concentration impurity regions, a drain metal silicide layer on each high-concentration impurity region, and a LDD between each high-concentration impurity region and the channel region. A gate pattern may be on the channel region and may include a gate metal silicide layer. Sidewall spacers may be on both sides of the gate pattern and may have a more narrow width than the LDDs. A stress liner may cover the gate pattern, the sidewall spacers, and the source and drain regions.

The sidewall spacers may have a width ranging from approximately 0.1 to 15 nm. In addition, the sidewall spacers may include an inner spacer contacting a sidewall of the gate pattern and an outer spacer covering an outer surface of the inner spacer. The outer spacer may be formed of a silicon nitride layer.

The channel region may include n-type or p-type impurity ions. When the channel region includes n-type impurity ions, the stress liner may be an insulating layer having compressive stress. The insulating layer having compressive stress may be a compressive nitride layer. When the channel region includes p-type impurity ions, the stress liner may be an insulating layer having tensile stress. The insulating layer having tensile stress may be a tensile nitride layer.

According to example embodiments, a semiconductor device having a stress enhanced MOS transistor may include a NMOS transistor and a PMOS transistor that are spaced apart from one another in a desired, or alternatively, a predetermined region of a semiconductor substrate.

The NMOS transistor may include source and drain regions spaced apart from one another in the semiconductor substrate, a gate pattern over the p-channel region between the source and drain regions, and sidewall spacers covering sidewalls of the gate pattern.

The PMOS transistor may include source and drain regions spaced apart from one another in the semiconductor substrate, a gate pattern over the n-channel between the source and drain regions, and sidewall spacers covering sidewalls of the gate pattern.

A tensile liner covering the NMOS transistor having the thinner spacers and a compressive liner covering the PMOS transistor having the thinner spacers may be formed.

### BRIEF DESCRIPTION OF THE DRAWINGS

Example embodiments will be more clearly understood from the following detailed description taken in conjunction with the accompanying drawings. FIGS. 1-13 represent non-limiting, example embodiments as described herein.

FIG. 1 is a cross-sectional view illustrating a method of forming a stress liner in a conventional MOS transistor having a metal silicide layer.

FIGS. 2 through 13 are cross-sectional views illustrating a method of fabricating a semiconductor device having a stress enhanced MOS transistor according to example embodiments.

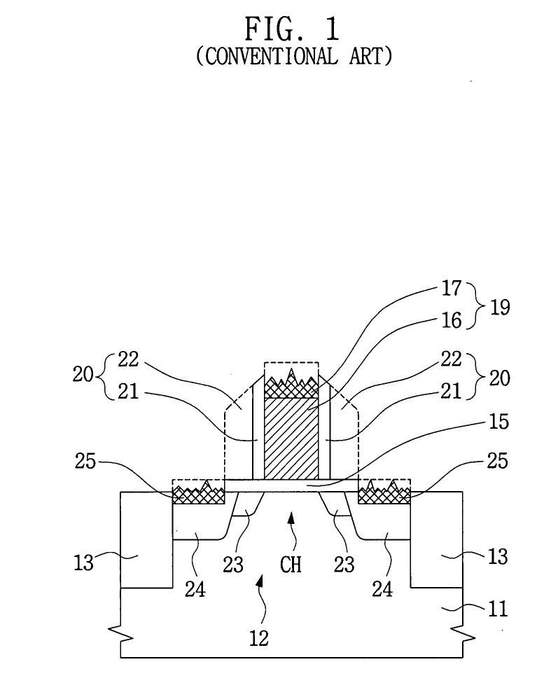

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

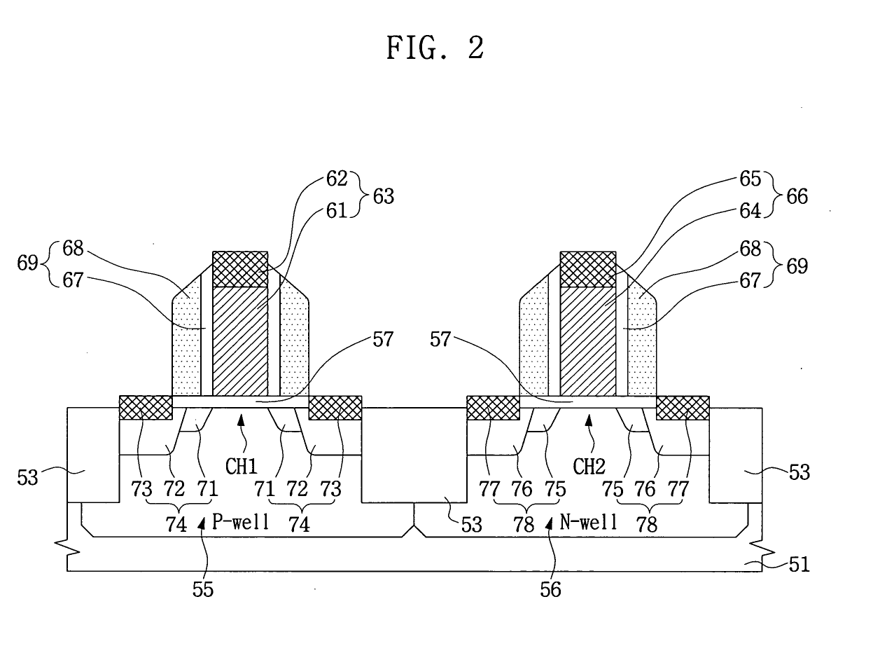

FIGS. 2-13 illustrate a method of fabricating a semiconductor device having a stress enhanced MOS transistor according to example embodiments.

Referring to FIG. 2, isolation layers 53 may be formed to define a first active region 55 and a second active region 56 in desired, or alternatively, predetermined regions of a semiconductor substrate 51. The semiconductor substrate 51 may be a silicon wafer or a silicon-on-insulator (SOI) wafer. The isolation layer 53 may be formed using a known shallow trench isolation (STI) technique. The isolation layer 53 may be an insulating layer, for example, a silicon oxide layer.

The first active region 55 and the second active region 56 may be spaced apart by the isolation layer 53. P-type impurity ions may be injected into the first active region 55. N-type impurity ions may be injected into the second active region 56. Thus, the first active region 55 may be a p-well, and the second active region 56 may be a n-well.

A gate dielectric layer 57 may be formed on the first active region 55 and the second active region 56. The gate dielectric layer 57 may be a silicon oxide layer or a high-k dielectric layer, for example, a metal oxide layer. A first gate electrode 61 and a second gate electrode 64 may be formed on the gate dielectric layer 57. Accordingly, the first gate electrode 61 may be formed on the first active region 55 and the second gate electrode 64 may be formed on the second active region 56. The first gate electrode 61 and the second gate electrode 64 may be formed of a conductive layer, for example, a polysilicon layer.

First and second lightly doped drains (LDDs) 71 and 75 may be formed in the first active region 55 and the second active region 56, respectively, and may be formed on both sides of the gate electrodes 61 and 64, respectively. The first LDDs 71 may be formed by injecting n-type impurity ions into the first active region 55. The second LDDs 75 may be formed by injecting p-type impurity ions into the second active region 56.

Sidewall spacers 69 may be formed on the sidewalls of the first and second gate electrodes 61 and 64. The sidewall spacers 69 may include an inner spacer 67 contacting the sidewalls of the first and second gate electrodes 61 and 64, and an outer spacer 68 contacting the outer surface of the inner spacer 67. The inner spacer 67 may be formed of a silicon oxide layer, for example, a thermal oxide layer. The inner spacer 67 may be formed to a thickness between approximately 0.1 to 15 nm. The outer spacer 68 may be formed of a nitride layer, for example, a silicon nitride layer.

N-type impurity ions may be injected into the first active region 55 using the first gate electrode 61 and the sidewall spacers 69 as ion injection masks to form first high-concentration impurity regions 72. The first LDDs 71 may remain under the sidewall spacers 69. P-type impurity ions may be injected into the second active region 56 using the second gate electrode 64 and the sidewall spacers 69 as ion injection masks to form second high-concentration impurity regions 76. The second LDDs 75 may remain under the sidewall spacers 69.

It will be understood by those skilled in the art that in forming a particular component of example embodiments, the other regions may be covered (usually with photoresist). Because the technique for forming a photoresist pattern and using the photoresist pattern as an etch mask may be well known to those skilled in the art, a description thereof is omitted.

Metal silicide layers 62 and 73 may be formed on the first gate electrode 61 and the first high-concentration impurity regions 72 using a salicide technique. Likewise, metal silicide layers 65 and 77 may be formed on the second gate electrode 64 and the second high-concentration impurity regions 76 using a salicide technique. The metal silicide layers 62, 65, 73, and 77 may be formed of a nickel silicide (NiSi) layer, a cobalt silicide (CoSi) layer, a platinum silicide (PtSi) layer, a nickel-platinum silicide (NiPtSi) layer, a tungsten silicide (WSi) layer, a titanium silicide (TiSi) layer, or etc.

Accordingly, the first metal silicide layer 62 may be formed on the first gate electrode 61, the first metal silicide layers 73 may be formed on the first high-concentration impurity regions 72, the second metal silicide layer 65 may be formed on the second gate electrode 64, and the second metal silicide layers 77 may be formed on the second high-concentration impurity regions 76.

The first gate electrode 61 and the first metal silicide layer 62 may constitute the gate pattern 63. The second gate electrode 64 and the second metal silicide layer 65 may constitute the gate pattern 66. The first LDDs 71, the first high-concentration impurity regions 72, and the first metal silicide layers 73 may constitute source and drain regions 74. The second LDDs 75, the second high-concentration impurity regions 76, and the second metal silicide layers 77 may constitute source and drain regions 78.

A first channel region CH1 may be formed in the first active region 55 between the source and drain regions 74. A second channel region CH2 may be formed in the second active region 56 between the source and drain regions 78. Accordingly, the channel regions CH1 and CH2 may be formed under the gate patterns 63 and 66. The first channel region CH1 may include p-type impurity ions, and the second channel region CH2 may include n-type impurity ions. Thus, the first channel region CH1 may be designated as a p-channel region, and the second channel region CH2 may be designated as a n-channel region.

A NMOS transistor may be formed by the first channel region CH1, the gate dielectric layer 57, the gate pattern 63, the sidewall spacers 69, and the source and drain regions 74. A PMOS transistor may be formed by the second channel region CH2, the gate dielectric layer 57, the gate pattern 66, the sidewall spacers 69, and the source and drain regions 78.

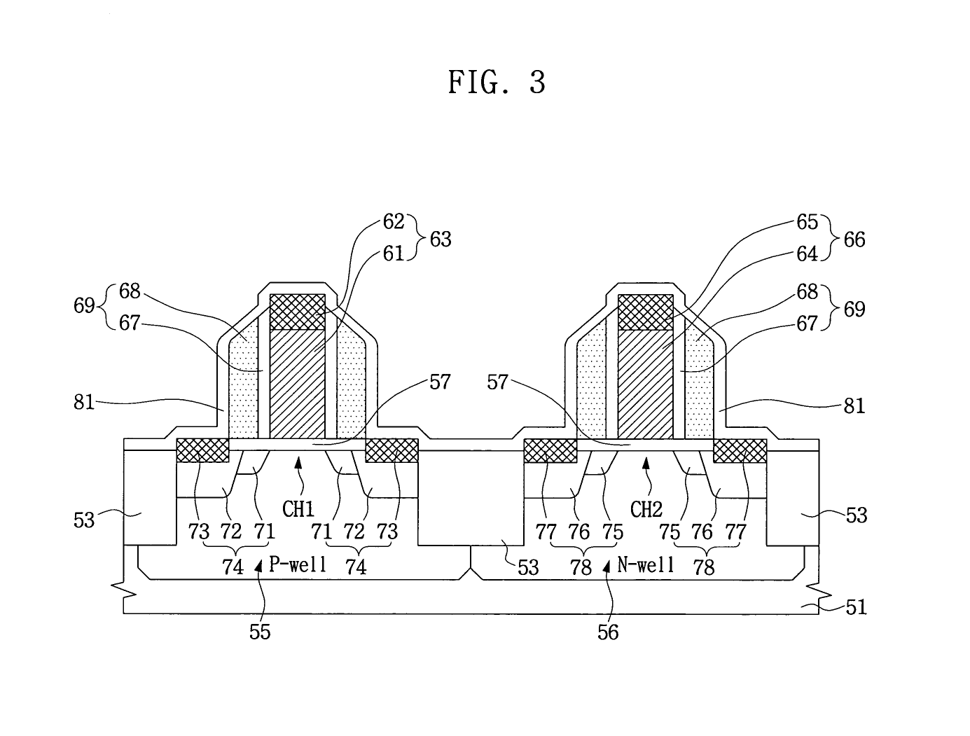

Referring to FIG. 3, a first sacrificial layer 81 may be formed on the semiconductor substrate 51 including the NMOS and PMOS transistors. The first sacrificial layer 81 may be formed of a material layer having an etch selectivity with respect to the inner and outer spacers 67 and 68. The first sacrificial layer 81 may be formed of a titanium nitride (TiN) layer, a low temperature oxide (LTO) layer, or a combination thereof. The LTO layer may include a plasma oxide layer that may be formed using a temperature ranging from approximately 400° to 450° C. The first sacrificial layer 81 may be formed to a thickness between approximately 1 to 15 nm.

Accordingly, the metal silicide layers 62, 65, 73, and 77, and the sidewall spacers 69 may be covered by the first sacrificial layer 81.

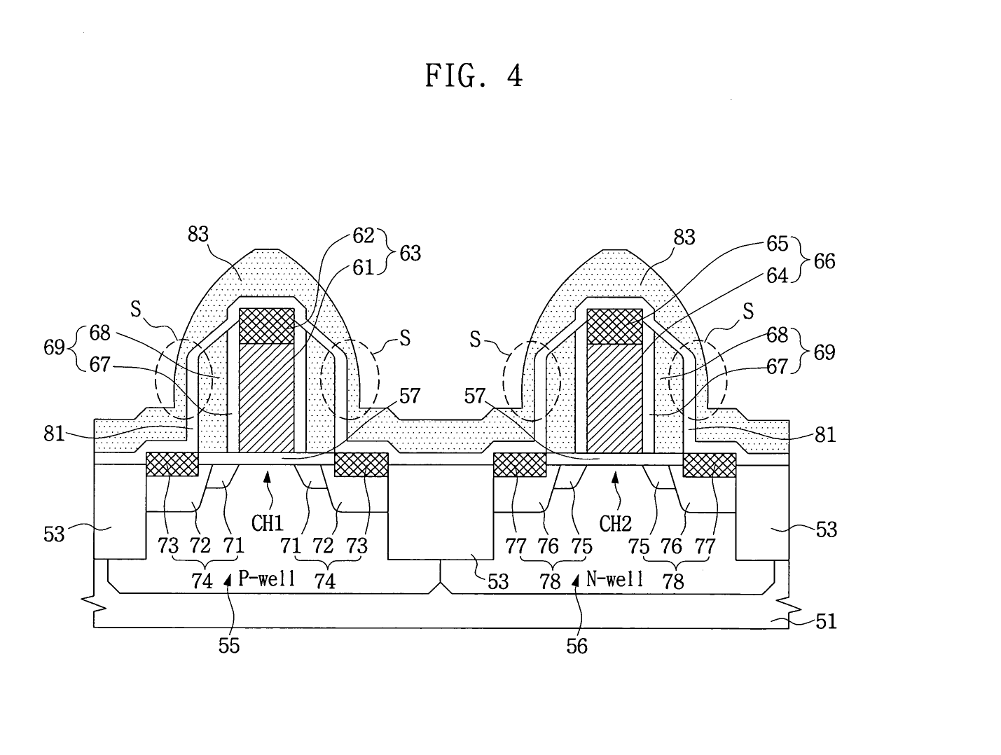

Referring to FIG. 4, a second sacrificial layer 83 may be formed over the semiconductor substrate 51 including the first sacrificial layer 81. The second sacrificial layer 83 may be formed on outer surfaces S of the sidewall spacers 69 and may be formed thinner than the second sacrificial layer 83 formed on the gate patterns 63 and 66, and the source and drain regions 74 and 78. The second sacrificial layer 83 may be formed of a material layer having an etch selectivity with respect to the first sacrificial layer 81. The second sacrificial layer 83 may be formed of a material layer having a similar etch rate to the outer spacer 68.

The second sacrificial layer 83 may be a nitride layer, for example, a high-density plasma (HDP) nitride layer. In forming the HDP nitride layer, deposition and sputter etch processes may be alternately and repeatedly performed. Accordingly, the deposition of the second sacrificial layer 83 may be inhibited on the outer surfaces S of the sidewall spacers 69, and the second sacrificial layer 83 may be formed thicker on the gate patterns 63 and 66 and the source and drain regions 74 and 78.

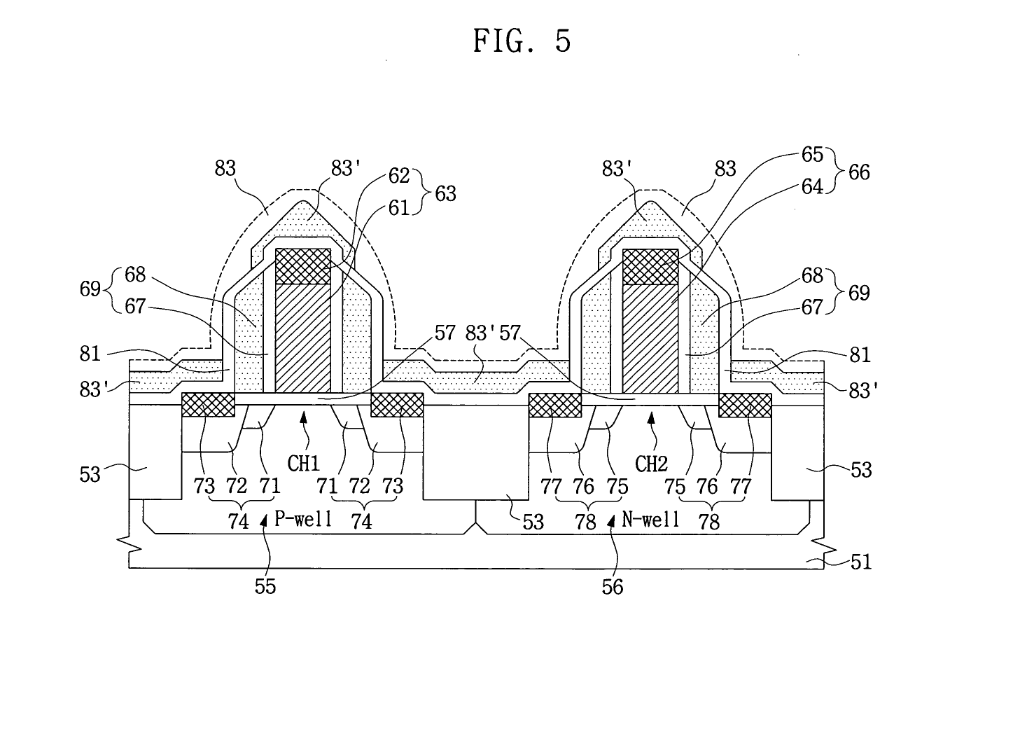

Referring to FIG. 5, a second sacrificial pattern 83′ may be formed by etching the second sacrificial layer 83. The etching of the second sacrificial layer 83 may include isotropically etching the second sacrificial layer 83 until the first sacrificial layer 81 is exposed.

As such, the first sacrificial layer 81 formed on the outer surface of the sidewall spacer 69 may be exposed. The second sacrificial pattern 83′ may cover top surfaces of the gate patterns 63 and 66, and the source and drain regions 74 and 78.

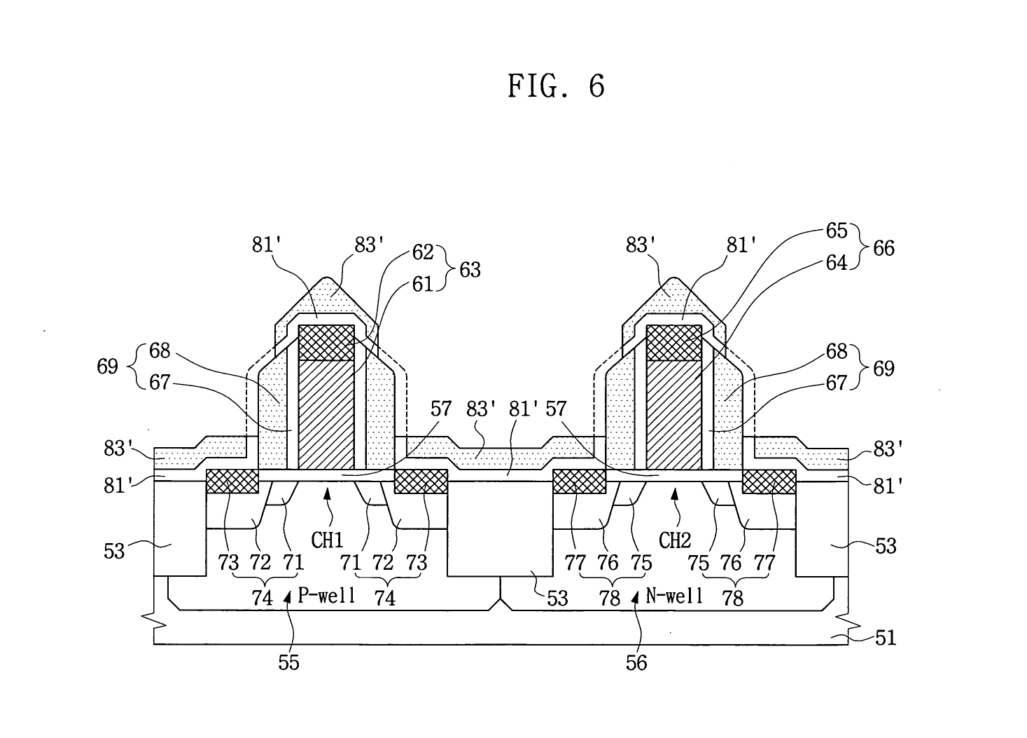

Referring to FIG. 6, the exposed first sacrificial layer 81 may be etched using the second sacrificial pattern 83′ as an etch mask to form a first sacrificial pattern 81′.

The first sacrificial pattern 81′ may cover the top surfaces of the gate patterns 63 and 66, and the source and drain regions 74 and 78. Thus, the metal silicide layers 62, 65, 73, and 77 may be covered by the first sacrificial pattern 81′. However, the sidewall spacers 69 may be partially exposed. Also, the second sacrificial pattern 83′ may remain on the first sacrificial pattern 81′.

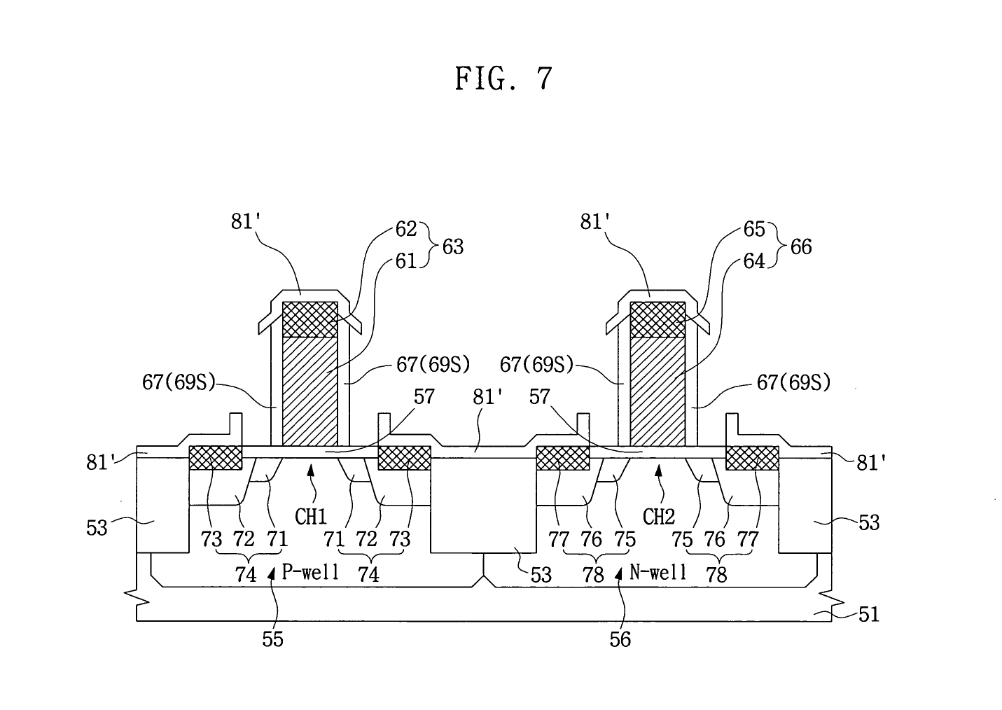

Referring to FIG. 7, the outer spacer 68 may be isotropically etched to expose the inner spacer 67. The inner spacer 67 may function as a thinner spacer 69S. The outer spacer 68 may be etched by a dry or a wet etching process. The thinner spacer 69S may be formed to be more narrow than the first and second LDDs 71 and 75.

The second sacrificial pattern 83′ may also be removed by etching. The first sacrificial pattern 81′ may remain on the gate patterns 63 and 66, and the source and drain regions 74 and 78. Thus, the metal silicide layers 62, 65, 73, and 77 may be protected from damage caused by the etching process.

According to example embodiments as described above, when the spacers 69 are etched to form the thinner spacers 69S, the first sacrificial pattern 81′ may protect the metal silicide layers 62, 65, 73, and 77 from damage caused by the etching process.

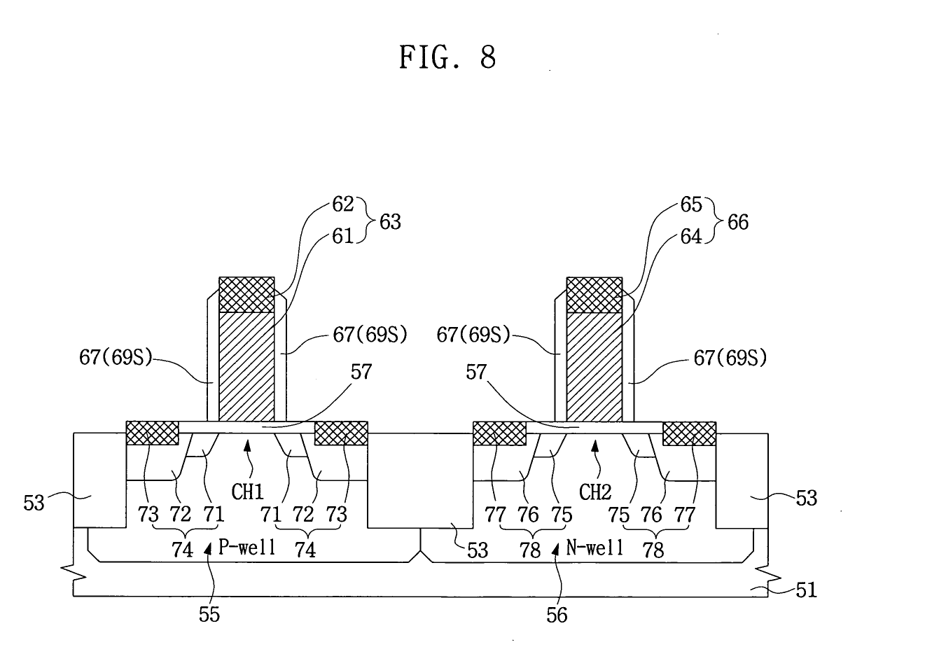

Referring to FIG. 8, the first sacrificial pattern 81′ may be etched to expose the metal silicide layers 62, 65, 73, and 77. When the first sacrificial pattern 81′ is a TiN layer, the first sacrificial pattern 81′ may be removed with aqua regia.

The forming of the NMOS and PMOS transistors having the thinner spacers 69S may then be completed.

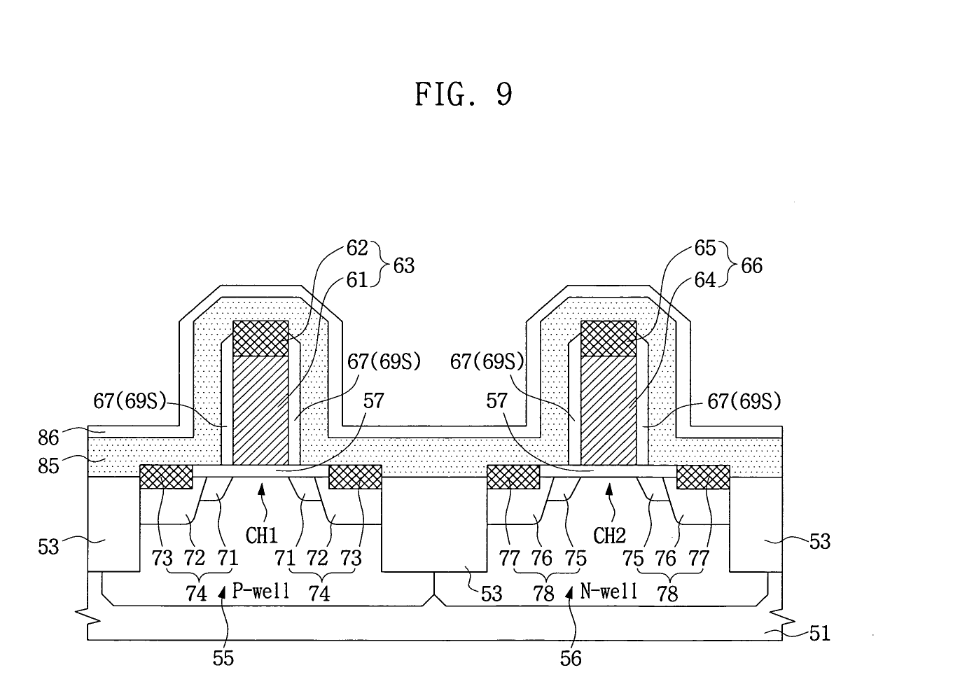

Referring to FIG. 9, a tensile layer 85 may be formed on the NMOS and PMOS transistors having the thinner spacers 69S. The tensile layer 85 may be an insulating layer having tensile stress. For example, the tensile layer 85 may be a tensile nitride layer.

An etch stop layer 86 may be formed on the tensile layer 85. The etch stop layer 86 may be a silicon oxide layer.

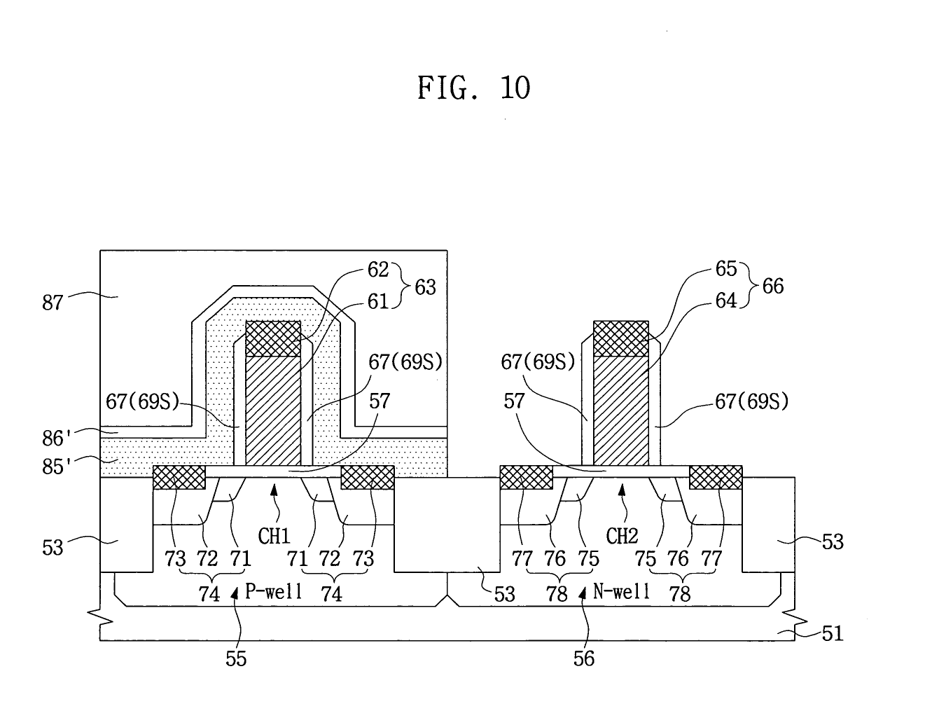

Referring to FIG. 10, a first mask pattern 87 may be formed on the etch stop layer 86. The NMOS transistor may be covered by the first mask pattern 87, whereas the PMOS transistor may be exposed. The etch stop layer 86 and the tensile layer 85 may be sequentially etched using the first mask pattern 87 as an etch mask to form an etch stop pattern 86′ and a tensile liner 85′. The first mask pattern 87 may then be removed.

Accordingly, the tensile liner 85′ may cover the NMOS transistor having the thinner spacers 69S. The etch stop pattern 86′ may remain on the tensile liner 85′.

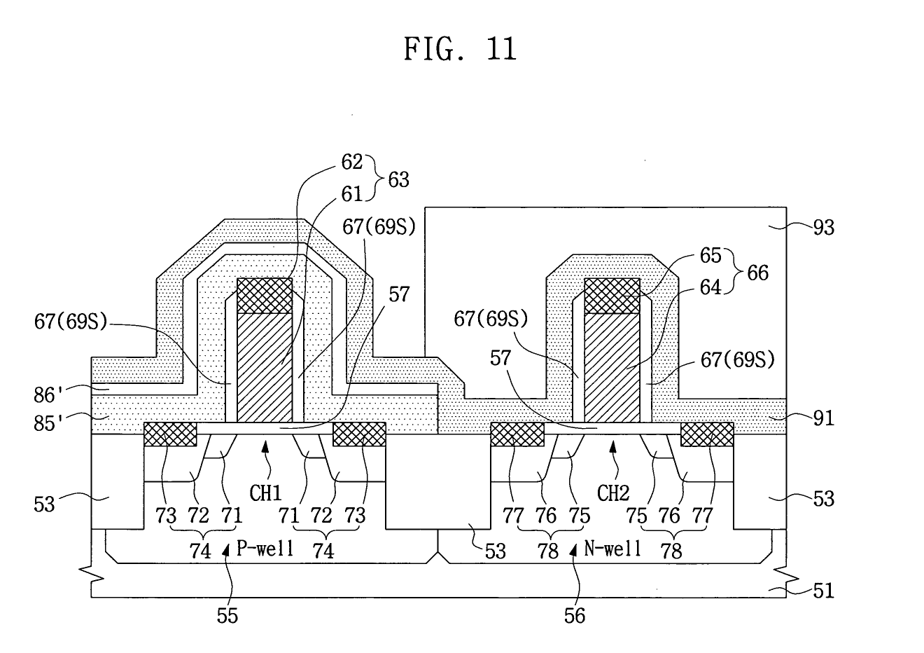

Referring to FIG. 11, a compressive layer 91 may be formed on the semiconductor substrate 51. The compressive layer 91 may be formed to cover the PMOS transistor having the thinner spacers 69S and to cover the etch stop pattern 86′. The compressive layer 91 may be an insulating layer having compressive stress. For example, the compressive layer 91 may be a compressive nitride layer. The etch stop pattern 86′ may be a material layer having an etch selectivity with respect to the compressive layer 91.

A second mask pattern 93 may be formed on the compressive layer 91. The PMOS transistor may be covered by the second mask pattern 93. However, the compressive layer 91 formed on the etch stop pattern 86′ may be exposed.

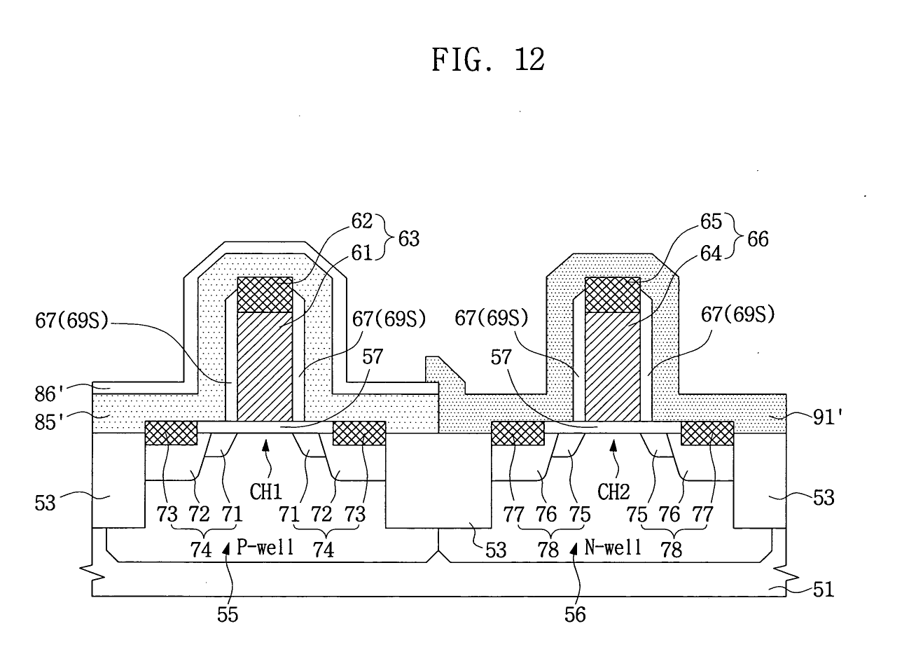

Referring to FIG. 12, the exposed compressive layer 91 may be etched using the second mask pattern 93 as an etch mask to form a compressive liner 91′. The second mask pattern 93 may then be removed.

Thus, the compressive liner 91′ may cover the PMOS transistor having the thinner spacers 69S.

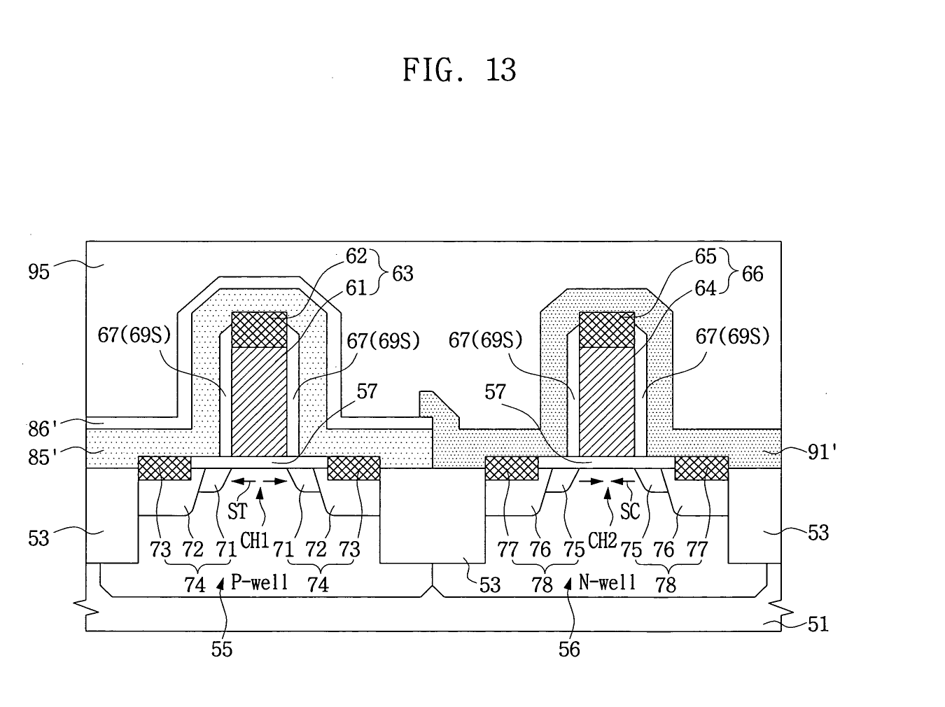

Referring to FIG. 13, an interlayer insulating layer 95 may be formed over the semiconductor substrate 51 having the tensile liner 85′ and the compressive liner 91′. The interlayer insulating layer 95 may be a silicon oxide layer.

As described above, the tensile liner 85′ may be formed over the NMOS transistor having the thinner spacers 69S, and the compressive liner 91′ may be formed over the PMOS transistor having the thinner spacers 69S. Thus, the tensile liner 85′ may cover the gate pattern 63, the thinner spacers 69S, and the source and drain regions 74. The compressive liner 91′ may cover the gate pattern 66, the thinner spacers 69S, and the source and drain regions 78.

The tensile liner 85′ may be an insulating layer having tensile stress, and the compressive liner 91′ may be an insulating layer having compressive stress. Accordingly, the first channel region CH1 may receive tensile stress (denoted as an arrow ST) from the tensile liner 85′, and the second channel region CH2 may receive compressive stress (denoted as an arrow SC) from the compressive liner 91′.

A semiconductor device having a stress enhanced MOS transistor according to example embodiments will now be described with reference to FIG. 13.

Referring to FIG. 13, isolation layers 53 defining first active region 55 and second active region 56 may be formed in desired, or alternatively, predetermined regions of a semiconductor substrate 51. The semiconductor substrate 51 may be a silicon wafer or a SOI wafer. The first active region 55 and the second active region 56 may be spaced apart by the isolation layer 53. The first active region 55 may include p-type impurity ions. The second active region 56 may include n-type impurity ions. Thus, the first active region 55 may be a p-well, and the second active region 56 may be a n-well.

Gate dielectric layers 57 may be formed on the first active region 55 and the second active region 56. The gate dielectric layer 57 may be a silicon oxide layer or a high-k dielectric layer, for example, a metal oxide layer. The first and second gate electrodes 61 and 64 may be formed on the gate dielectric layers 57. Accordingly, the first gate electrode 61 may be formed on the first active region 55 and the second gate electrode 64 may be formed on the second active region 56. The first and second gate electrodes 61 and 64 may be conductive layers, for example, polysilicon layers.

A first gate metal silicide layer 62 may be formed on the first gate electrode 61, and a second metal silicide layer 65 may be formed on the second gate electrode 64. The first gate electrode 61 and the first metal silicide layer 62 may constitute the gate pattern 63. The second gate electrode 64 and the second metal silicide layer 65 may constitute the gate pattern 66.

Source and drain regions 74, formed on both sides of the gate pattern 63, may be formed in the first active region 55, and may be spaced apart from one another. The source and drain regions 74 may include first LDDs 71, first high-concentration impurity regions 72, and first metal silicide layers 73. A first channel region CH1 may be formed in the first active region 55 between the source and drain regions 74. Thus, the first channel region CH1 may be formed under the gate pattern 63. The first channel region CH1 may include p-type impurity ions.

The first LDDs 71 may be formed between the first channel region CH1 and the first high-concentration impurity regions 72. The first metal silicide layers 73 may be formed on the first high-concentration impurity regions 72.

Source and drain regions 78, formed on both sides of the gate pattern 66, may be formed in the second active region 56, and may be spaced apart from one another. The source and drain regions 78 may include second LDDs 75, second high-concentration impurity regions 76, and second metal silicide layers 77. A second channel region CH2 may be formed in the second active region 56 between the source and drain regions 78. Thus, the second channel region CH2 may be formed under the gate pattern 66. The second channel region CH2 may include n-type impurity ions.

The second LDDs 75 may be formed between the second channel region CH2 and the second high-concentration impurity regions 76. The second metal silicide layers 77 may be formed on the second high-concentration impurity regions 76.

Thinner spacers 69S may be formed on the sidewalls of the gate patterns 63 and 66. The thinner spacers 69S may be more narrow than the first and second LDDs 71 and 75. The thinner spacers 69S may have a width ranging from approximately 0.1 to 15 nm. The thinner spacers 69S may be an insulating layer, for example, a silicon oxide layer.

A NMOS transistor may include the first channel region CH1, the gate dielectric layer 57, the gate pattern 63, the thinner spacers 69S, and the source and drain regions 74. A PMOS transistor may include the second channel region CH2, the gate dielectric layer 57, the gate pattern 66, the thinner spacers 69S, and the source and drain regions 78.

Stress liners 85′ and 91′ covering the transistors may be formed. The stress liners 85′ and 91′ may include a tensile liner 85′ covering the NMOS transistor and a compressive liner 91′ covering the PMOS transistor. Thus, the tensile liner 85′ may be formed to cover the gate pattern 63, the thinner spacers 69S, and the source and drain regions 74. The compressive liner 91′ may be formed to cover the gate pattern 66, the thinner spacers 69S, and the source and drain regions 78.

The tensile liner 85′ may be an insulating layer having tensile stress. The insulating layer having tensile stress may be a tensile nitride layer. The compressive liner 91′ may be an insulating layer having compressive stress. The insulating layer having compressive stress may be a compressive nitride layer.

An etch stop pattern 86′ may be formed on the tensile liner 85′. The etch stop pattern 86′ may be a material layer having an etch selectivity according to the compressive liner 91′. The etch stop pattern 86′ may not be an essential component, and thus, may be omitted. An interlayer insulating layer 95 may be formed over the semiconductor substrate 51. The interlayer insulating layer 95 may be a silicon oxide layer.

As described above, the thinner spacers 69S, which may be more narrow than the first and second LDDs 71 and 75, may be formed on the sidewalls of the gate patterns 63 and 66. Thus, the physical stress applied to the channel regions CH1 and CH2 from the stress liners 85′ and 91′ may be greater than that of a conventional device. The first channel region CH1 may receive tensile stress (denoted as an arrow ST) from the tensile liner 85′, and the second channel region CH2 may receive compressive stress (denoted as an arrow SC) from the compressive liner 91′.

According to example embodiments described above, a first sacrificial pattern, formed over the source and drain regions of a MOS transistor, may expose the sidewall spacers and cover the upper part of the gate pattern. The exposed sidewall spacers may be etched using the first sacrificial pattern as an etch mask to form thinner spacers. The thinner spacers may be more narrow than the LDDs of the MOS transistor. The first sacrificial pattern may reduce or prevent etching damage to metal silicide layers included in the gate pattern and the source and drain regions.

A stress liner may be formed over a MOS transistor having the thinner spacers. The thinner spacers may reduce or minimize the distance between the channel region under the gate pattern and the stress liner. Thus, the physical stress applied to the channel region from the stress liner may be increased or maximized. As such, a semiconductor device having a high-performance MOS transistor may be fabricated.

Although example embodiments have been shown and described in this specification and figures, it would be appreciated by those skilled in the art that changes may be made to the illustrated and/or described example embodiments without departing from their principles and spirit.

What is claimed is:

1. A method of fabricating a semiconductor device, comprising:
forming at least one MOS transistor in a semiconductor substrate, the at least one MOS transistor having source and drain regions spaced apart from each other in the semiconductor substrate, a gate pattern formed over a channel region between the source and drain regions, and at least one sidewall spacer covering at least one sidewall of the gate pattern;
forming a first sacrificial pattern covering the source and drain regions, exposing the sidewall spacer, and covering an upper region of the gate pattern;
etching the exposed sidewall spacer using the first sacrificial pattern as an etch mask to form a thinner sidewall spacer; and
forming a stress liner over the at least MOS transistor having the thinner sidewall spacer.

2. The method according to claim 1, wherein the channel region is a p-channel region and the MOS transistor is a NMOS transistor.

3. The method according to claim 1, wherein the channel region is a n-channel region and the MOS transistor is a PMOS transistor.

4. The method according to claim 1, wherein the MOS transistor is a NMOS transistor and the stress liner is a tensile liner.

5. The method according to claim 1, wherein the MOS transistor is a PMOS transistor and the stress liner is a compressive liner.

6. The method according to claim 1, wherein forming the first sacrificial pattern comprises:
forming a first sacrificial layer covering the at least one MOS transistor;
forming a second sacrificial layer over the first sacrificial layer, the second sacrificial layer formed over an outer surface of the sidewall spacer being thinner than that formed over the gate pattern and the source and drain regions;
forming a second sacrificial pattern by etching the second sacrificial layer until the first sacrificial layer over the outer surface of the sidewall spacer is exposed; and
etching the exposed first sacrificial layer until the sidewall spacer is exposed.

7. The method according to claim 6, wherein the second sacrificial layer is formed of a high-density plasma (HDP) nitride layer.

8. The method according to claim 6, wherein the second sacrificial pattern is removed when the exposed sidewall spacer is etched.

9. The method according to claim 1, further comprising:
removing the first sacrificial pattern after the thinner sidewall spacer has been formed.

10. The method according to claim 1, wherein the gate pattern includes a metal silicide layer.

11. The method according to claim 1, wherein the source and drain regions include a pair of high-concentration impurity regions, a pair of lightly doped drains (LDDs), and a metal silicide layer formed over each high-concentration impurity region.

12. The method according to claim 11, wherein each LDD is formed between one of the high-concentration impurity regions and the channel region.

13. The method according to claim 1, wherein the sidewall spacer includes an inner spacer contacting a sidewall of the gate pattern and an outer spacer covering an outer surface of the inner spacer.

14. The method according to claim 13, wherein the outer spacer is formed of a silicon nitride layer.

15. The method according to claim 13, wherein forming the thinner spacer includes isotropically etching the outer spacer and exposing the inner spacer.

16. The method according to claim 13, wherein the first sacrificial pattern is formed of a material layer having an etch selectivity with respect to the inner and outer spacers.

17. The method according to claim 1, wherein the first sacrificial pattern is formed of a titanium nitride (TiN) layer, a low temperature oxide (LTO) layer, or a combination thereof.

18. The method according to claim 1, wherein the channel region includes one of n-type or p-type impurity ions.

19. The method according to claim 18, wherein n-type impurity ions are injected into the channel region and the stress liner is formed of an insulating layer having compressive stress.

20. The method according to claim 19, wherein the insulating layer having compressive stress is a compressive nitride layer.

21. The method according to claim 18, wherein p-type impurity ions are injected into the channel region and the stress liner is formed of an insulating layer having tensile stress.

22. The method according to claim 21, wherein the insulating layer having tensile stress is a tensile nitride layer.

23. The method according to claim 1, wherein the forming of the at least one MOS transistor includes forming NMOS and PMOS transistors spaced apart from each other in predetermined regions of the semiconductor substrate, the channel region of the NMOS transistor being a p-channel region and the channel region of the PMOS transistor being a n-channel region, and the stress liner of the NMOS transistor being a tensile liner and the stress liner of the PMOS transistor being a compressive liner.

24. The semiconductor device fabricated by the method according to claim 1.

25. A semiconductor device comprising:
at least one MOS transistor in a semiconductor substrate, the at least one MOS transistor including,
source and drain regions spaced apart from each other in the semiconductor substrate and including a pair of lightly doped drains (LDDs),
a gate pattern over a channel region between the source and drain regions,
at least one sidewall spacer covering at least one sidewall of the gate pattern and having a more narrow width than the LDDs; and
a stress liner over the at least one MOS transistor.

26. The semiconductor device according to claim 25, further comprising:
a metal silicide layer over the gate pattern.

27. The semiconductor device according to claim 25, wherein the source and drain regions include a pair of high-concentration impurity regions and a metal silicide layer formed on each high-concentration impurity region.

28. The semiconductor device according to claim 27, wherein each LDD is formed between one of the high-concentration impurity regions and the channel region.

29. The semiconductor device according to claim 25, wherein the spacer has a width ranging from approximately 0.1 to 15 nm.

30. The semiconductor device according to claim 25, wherein the sidewall spacer includes an inner spacer contacting a sidewall of the gate pattern and an outer spacer covering an outer surface of the inner spacer.

31. The semiconductor device according to claim 30, wherein the outer spacer is formed of a silicon nitride layer.

32. The semiconductor device according to claim 25, wherein the channel region includes n-type impurity ions and the stress liner is formed of an insulating layer having compressive stress.

33. The semiconductor device according to claim 32, wherein the insulating layer having compressive stress is a compressive nitride layer.

34. The semiconductor device according to claim 25, wherein the channel region includes p-type impurity ions and the stress liner is formed of an insulating layer having tensile stress.

35. The semiconductor device according to claim 34, wherein the insulating layer having tensile stress is a tensile nitride layer.

36. The semiconductor device according to claim 25, wherein the channel region is a p-channel region and the MOS transistor is a NMOS transistor.

37. The semiconductor device according to claim 25, wherein the channel region is a n-channel region and the MOS transistor is a PMOS transistor.

38. The semiconductor device according to claim 25, wherein the MOS transistor is a NMOS transistor and the stress liner is a tensile liner.

39. The semiconductor device according to claim 25, wherein the MOS transistor is a PMOS transistor and the stress liner is a compressive liner.

40. The semiconductor device according to claim 25, wherein the at least one MOS transistor includes NMOS and PMOS transistors spaced apart from each other in predetermined regions of the semiconductor substrate, the channel region of the NMOS transistor being a p-channel region and the channel region of the PMOS transistor being a n-channel region, and the stress liner of the NMOS transistor being a tensile liner and the stress liner of the PMOS transistor being a compressive liner.
